(19) United States
(12) Patent Application Publication
(10) Pub. No.: US 2005/0032363 A1
(43) Pub. Date: Feb. 10, 2005

(54) Method for manufacturing a semiconductor device

(76) Inventor: Yoshiharu Ajiki, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/886,507

(22) Filed: Jul. 7, 2004

(30) Foreign Application Priority Data
Jul. 14, 2003 (JP) 2003-196685

(51) Int. Cl. H01L 21/44; H01L 21/302

(52) U.S. Cl. 438/664; 438/655; 438/660; 438/682; 438/755

(57) ABSTRACT

A method is provided for manufacturing a semiconductor device wherein a protective film is removed substantially without etching a compound film. A titanium film and a titanium nitride film are formed on a silicon layer in this order. A titanium silicide film is then formed by heat treating an SOI substrate. Subsequently, the titanium nitride film and the titanium film remaining unreacted are removed. The titanium film is formed to have a predetermined thickness so that the titanium film remains unreacted on the entire surface of the titanium silicide film after forming the titanium silicide film with a desired thickness. The nitride film and the titanium film remaining unreacted are removed by a wet etching method using a hydrofluoric acid solution.

### RELATED APPLICATIONS

This application claims priority to Japanese Patent Application No. 2003-196685 filed Jul. 14, 2003 which is hereby expressly incorporated by reference herein in its entirety.

### BACKGROUND

1. Field of the Invention

The present invention relates to a method for manufacturing a semiconductor device, and more particularly to a method for manufacturing a semiconductor device that, when providing a titanium silicide film (C49-TiSi₂ phase), forms a titanium film thick enough on a silicon layer so that the titanium film will remain unreacted on the entire surface of the titanium suicide film, and thus the titanium film and a titanium nitride film provided on the titanium film can be selectively removed from the titanium silicide film in a subsequent step.

2. Description of Related Art

In order to reduce parasitic capacitance factors in a metal-oxide semiconductor (MOS) transistor, a conventional method has been used for converting the gate electrode or source or drain (S/D) region into titanium (Ti) silicide (see Japanese Unexamined Patent Publication No. 11-238878, for example).

In particular, when forming a MOS transistor of the complete depletion mode provided on a silicon-on-insulator (SOI) substrate, parasitic capacitance factors in its S/D region are considerably large as the S/D region is formed on a thin silicon layer as thick as about 50 nm, compared to a MOS transistor formed on a bulk silicon substrate. Therefore, the S/D region is converted into silicide as a general method for reducing the parasitic capacitance factors in the S/D region when forming such a complete-depletion MOS transistor.

FIGS. 3(A) through (C) illustrate steps for forming a titanium silicide film (TiSi₂) 211 for showing a conventional example. FIG. 3(A) shows a silicon substrate (SUB) 201, an insulating layer (BOX) 203, and a silicon layer (SOI layer) 205.

The silicon substrate 201, the insulating layer 203, and the silicon layer 205 make up an SOI substrate 250. The drawing also shows a titanium film 207 and a titanium nitride (TiN) film 209.

When forming a titanium silicide film 211 on the silicon layer 205, first the titanium film 207 is provided on the silicon layer 205 as shown in FIG. 3(A). Next, the titanium nitride film 209 as a cap layer is deposited on the titanium film 207.

In FIG. 3(A), the film thickness of the titanium film 207 is about 20 nm, while that of the titanium nitride film 209 is about 15 nm. When forming such a complete-depletion MOS transistor, since the silicon layer 205 is typically as thin as 50 nm or less, making it necessary to make the silicide film thin, the titanium film and the titanium nitride film are generally deposited as thinly as possible.

Here, it is extremely difficult for current sputtering devices to achieve the uniformity in film thickness as small as around 15 to 20 nm. As a result, the film thickness of the titanium film 207 and that of the titanium nitride film 209 are uneven in the same wafer as shown in FIG. 3 (A).

Next, the SOI substrate 250, on which the titanium nitride film 209 is provided, is subjected to a first heat treatment process (first rapid thermal anneal, RTA). Through the first RTA, the titanium film 207 reacts with the upper part of the silicon layer 205 to form the titanium silicide film 211, as shown in FIG. 3(B). The titanium silicide film 211 formed through the first RTA has the formation of C49-TiSi₂ with a high electric resistance. Its thickness is about 20 nm. At this first RTA stage, the titanium film 207 may remain between the titanium silicide film 211 and the titanium nitride film 209 in parts where the titanium film 207 has been built up thickly as shown in FIG. 3(B).

Subsequently, the titanium nitride film 209 developed by the first RTA and the titanium film 207 partially remaining unreacted are etched and removed. Here, a liquid mixture of ammonium hydroxide (NH₄OH) and hydrogen peroxide (H₂O₂) is used as a etchant for the etching. The liquid mixture of ammonium hydroxide and hydrogen peroxide, however, etches not only the titanium nitride film 209 and the titanium film 207 remaining unreacted, but also the titanium silicide film 211. In other words, it does not provide sufficient etching selectivity among the titanium nitride film 209, the titanium film 207, and the titanium silicide film 211.

If the titanium silicide film 211 is largely etched, parasitic capacitance factors in the S/D region may increase. Therefore, etching conditions are set to be “under” so as not to etch the titanium suicide film 211 and prevent such parasitic capacitance factors from increasing. Subsequently, the SOI substrate 250 is subjected to a second heat treatment process (second RTA). Through the second RTA, the titanium silicide film 211 undergoes a phase transition from the formation of C49-TiSi₂ with a high electric resistance into the formation of C54-TiSi₂ with a low electric resistance, which completes the process for forming the titanium silicide film 211.

According to the above-mentioned conventional method for forming the titanium silicide film 211, the titanium nitride film 209 is wet etched and removed with the liquid mixture of ammonium hydroxide and hydrogen peroxide, which does not provide sufficient etching selectivity between the titanium nitride film 209 and the titanium silicide film 211. Therefore, the titanium nitride film 209 cannot be overetched.

This involves the following problems. As FIG. 3(C) shows, the titanium nitride film 209 tends to remain unetched especially in parts where the titanium nitride film 209 is built up thickly. The titanium nitride film 209 partially remaining on the titanium silicide film 211 may result in a decline in the performance of a device formed on the SOI substrate 250.

For example, if the SOI substrate 250 is subjected to the second RTA with the titanium nitride film 209 partially remaining on the titanium silicide film 211 (or called a “compound film” below), off-leakage current in a MOS transistor in a region where the titanium nitride film 209 (or called a “protective film” below) remains tends to become higher than usual (see Ajiki et al., Extended Abstracts, The 50th Meeting of the Japan Society of Applied Physics and Related Societies, 2003, for example).

In order to address these problems, the present invention aims to provide a method for manufacturing a semiconductor device by which the protective film is removed substantially without etching the compound film.

### SUMMARY

In order to solve the problems, a method for manufacturing a semiconductor device according to a first embodiment of the present invention includes the following steps: forming a metal film on an impurity diffusion layer provided in a semiconductor substrate so as to form a compound film with the impurity diffusion layer, the metal film having a predetermined thickness so that the metal film remains unreacted on the entire surface of the compound film after forming the compound film with a desired thickness; forming a protective film on the metal film; forming the compound film by heat treating the semiconductor substrate on which the protective film is formed so as to make the metal film react with an upper part of the impurity diffusion layer; and removing the protective film and the metal film remaining unreacted after forming the compound film, the protective film and the metal film being removed by using an etching process with an etching rate of the metal film that is larger than an etching rate of the compound film.

Here, the semiconductor substrate refers to a bulk silicon substrate or SOI substrate, for example. The impurity diffusion layer provided in the semiconductor substrate is a source- or drain-diffusion layer formed by implanting a conductive impurity such as phosphorus, boron, and arsenic, in a silicon layer of such a bulk silicon substrate or SOI substrate. Alternatively, the impurity diffusion layer is a silicon film formed on a silicon substrate or an SOI substrate with an insulating film therebetween, and is a gate electrode formed by implanting a conductive impurity such as phosphorus, boron, and arsenic.

The method for manufacturing a semiconductor device according to the first embodiment of the present invention makes it possible to, when removing the protective film and the metal film remaining unreacted, remove the protective film above the compound film substantially without etching the compound film. Thus, for example, it is expected that no decrease in the performance of a device results and an increase in yield is achieved by, for example, reducing leakage current in a MOS transistor.

In a method for manufacturing a semiconductor device according to a second embodiment of the present invention, the protective film and the metal film remaining unreacted in the first embodiment are removed by using an etching process with an etching rate of the metal film that is larger than an etching rate of the protective film.

In a method for manufacturing a semiconductor device according to a third embodiment of the present invention, the semiconductor substrate of the first or second emobdiments is an SOI substrate, the metal film is a titanium film, and the protective film is a titanium nitride film.

In a method for manufacturing a semiconductor device according to a fourth embodiment of the present invention, the etching process of the third embodiment is a wet etching method using a solution including hydrofluoric acid.

By the method for manufacturing a semiconductor device according to any one of the second through fourth embodiments of the present invention, when removing the protective film and the metal film remaining unreacted, once parts of the metal film start to be exposed under the protective film, the exposed metal film is etched faster than the protective film. This makes it possible to horizontally etch the metal film covered by the protective film, thereby lifting off the protective film.

### BRIEF DESCRIPTION OF THE DRAWINGS

FIGS. 1(A)-(C) show first steps for forming a titanium silicide film 111 according to an embodiment of the present invention.

FIGS. 2(A)-(B) show second steps for forming the titanium silicide film 111.

FIGS. 3(A)-(C) show steps for forming a titanium silicide film 211 of a conventional example.

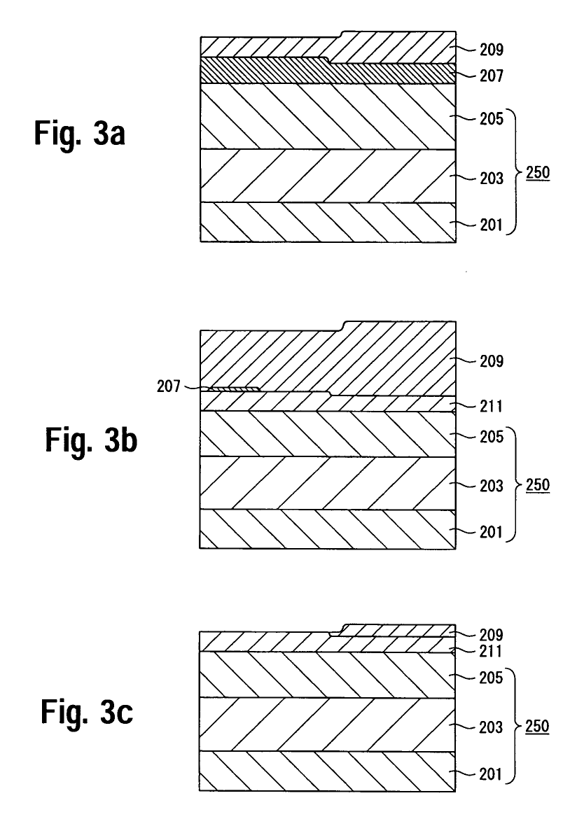

### DETAILED DESCRIPTION

A method for manufacturing a semiconductor device according to an embodiment of the present invention will now be described with reference to the accompanying drawings.

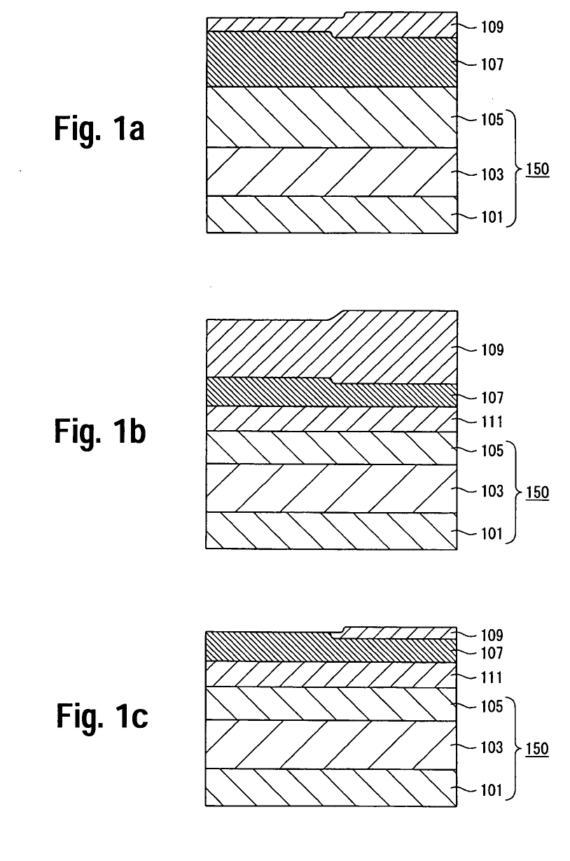

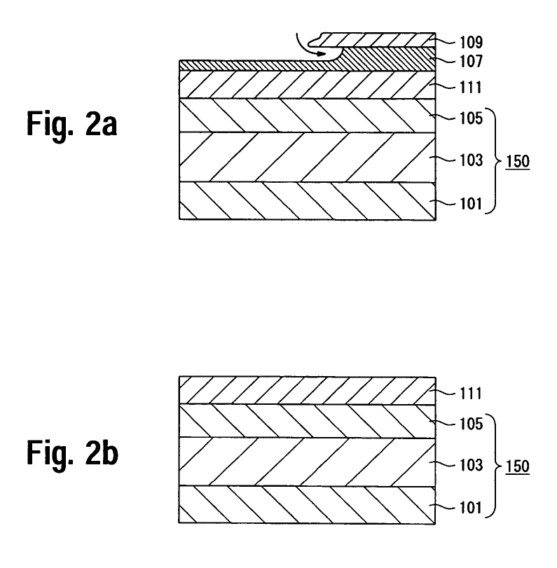

FIGS. 1(A) through 2 (B) illustrate steps for forming a titanium silicide film 111 according to an embodiment of the present invention. This embodiment describes forming the titanium silicide film 111 to about 20 nm thick on the S/D region of a complete-depletion MOS transistor (not shown in the drawings) formed on an SOI substrate 150.

FIG. 1(A) shows a silicon substrate (SUB) 101, an insulating layer (BOX) 103, and a silicon layer (SOI layer) 105. The silicon substrate 101, the insulating layer 103, and the silicon layer 105 make up the SOI substrate 150.

The silicon layer 105 is about 50 nm thick, for example. A conductivity type impurity such as phosphorus and boron is ion implanted into this silicon layer 105 so as to form the S/D region of the complete-depletion MOS transistor.

First, a titanium film 107 is provided on the silicon layer 105, which is the S/D region of the complete-depletion MOS transistor, as shown in FIG. 1(A). The titanium film 107 of about 30 nm thick (an example of predetermined thickness) is formed by, for example, a sputtering method sputtering the titanium target with argon ions (Ar⁺) and attaching recoil titanium atoms to a wafer.

As described in the conventional example above, it is sufficient to have the titanium film 107 of about 20 nm thick for forming the titanium silicide film 111 of about 20 nm thick. Here, however, considering leaving the titanium film 107 of about 10 nm thick on the entire surface of the titanium silicide film 111 after providing the titanium silicide film 111 of about 20 nm thick in a first RTA step that will be mentioned later, the titanium film 107 is built up thickly.

As shown in FIG. 1(A), it is common that the film thickness of the titanium film 107 is uneven in a single wafer. This is because it is difficult with current technology to achieve the uniformity in thickness as small as around 30 nm in a single wafer by a sputtering method, as mentioned above in the conventional example.

Next, the titanium film 109 is provided on the titanium film 107. The titanium nitride film 109 of about 15 nm thick is formed by, for example, a sputtering method sputtering the titanium nitride target with argon ions (Ar⁺). The titanium nitride film 109 serves as a cap layer for preventing oxygen etc. from entering the titanium film in the subsequent first RTA step. Since the film thickness of the titanium nitride film 109 is smaller than that of the titanium film 107, on which the titanium nitride film 109 is deposited, it is common that the film thickness of the titanium nitride film 109 is more uneven than that of the titanium film 107 as shown in FIG. 1(A).

Next, the SOI substrate 150, on which the titanium nitride film 109 is provided, is subjected to the first heat treatment process (first RTA). Through the first RTA, the lower part of the titanium film 107 reacts with the upper part of the silicon layer 105 to form the titanium silicide film 111 of about 20 nm thick (an example of predetermined thickness), as shown in FIG. 1(B). The titanium silicide film 111 formed through the first RTA has the formation of C49-TiSi₂ with a high electric resistance. The first RTA is performed by, for example, annealing the SOI substrate 150 in a nitrogen atmosphere at around 540 degrees centigrade for about 60 seconds.

As FIG. 1(B) shows, the titanium film 107 of about 10 nm thick remains unreacted on the entire surface of the titanium silicide film 111 that has been formed as mentioned above. Also through the first RTA, the titanium nitride film 109 is developed from about 15 nm thick to about 55 nm thick.

The forming of the titanium silicide film 111 is followed by removal of the titanium nitride film 109 and the titanium film 107 remaining unreacted and covering the entire surface of the titanium silicide film 111.

The removal of the titanium nitride film 109 and the titanium film 107 is performed by wet etching with a hydrofluoric acid solution, for example. Alternatively, wet etching may be by a dip or spray method. The etching is performed for 12 minutes, for example.

In the wet etching with a hydrofluoric acid solution, the ratio of etching (hereinafter called an “etching selectivity ratio”) among the titanium nitride film 109, the titanium film 107, and the titanium silicide film 111 is about 10:300:2.5.

Therefore, when applying the hydrofluoric acid solution to the SOI substrate 150, first the titanium nitride film 109 is etched and its film thickness becomes smaller. As a result, the titanium film 107 starts to be exposed, starting from in parts where the film thickness of the titanium nitride film 109 is small, as shown in FIG. 1(C). Once parts of the titanium film 107 start to be exposed under the titanium nitride film 109, the titanium film 107 that is exposed is etched faster than the titanium nitride film 109. Therefore, parts of the titanium film 107 that are still covered by the titanium nitride film 109 can be etched horizontally with the hydrofluoric acid solution as indicated by an arrow in FIG. 2(A), lifting off the titanium nitride film 109.

Since the titanium silicide film 111 under the titanium film 107 is more resistant to etching with the hydrofluoric acid solution (that is, providing sufficient etching selectivity) compared to the titanium film 107, it is possible to remove the titanium film 107 and the titanium nitride film 109 on the titanium film 107 substantially without etching the titanium silicide film 111.

Subsequently, the SOI substrate is subjected to a second heat treatment process (second RTA). The second RTA is performed by, for example, annealing the SOI substrate 150 in a nitrogen atmosphere at around 710 degrees centigrade for about 30 seconds. Through the second RTA, the titanium silicide film 111 undergoes a phase transition from the formation of C49-TiSi₂ with a high electric resistance into the formation of C54-TiSi₂ with a low electric resistance, which completes the process for forming the titanium silicide film 111.

In this way, the process for forming the titanium silicide film 111 according to the present invention makes it possible to lift off the titanium nitride film 109 substantially without etching the titanium silicide film 111 while the removal of the titanium film 107 remaining unreacted and covering the entire surface of the titanium silicide film 111 and of the titanium nitride film 109 provided on the titanium film 107. This means that the titanium nitride film 109 can be removed with high reproducibility. Thus, it is expected that no decrease in the performance of a device will result and an increase in yield is achieved by, for example, reducing leakage currents in a MOS transistor.

In this embodiment, the SOI substrate 150 corresponds to the semiconductor substrate of the present invention, and the silicon layer 105 (S/D region) corresponds to the impurity diffusion layer of the invention. The titanium silicide film 111 corresponds to the compound film of the invention, and the titanium film 107 corresponds to the metal film of the invention. The titanium nitride film 109 corresponds to the protective film of the invention, and the wet etching using a hydrofluoric acid solution corresponds to the etching process of the invention.

While the titanium silicide film is formed on the silicon layer (S/D region) in this embodiment, applications of the present invention are not limited to this. For example, the present invention can be applied to forming a titanium silicide film on a gate electrode made of phosphorus- or boron-doped polysilicon etc., and also to forming of a titanium silicide film on both of such a gate electrode and the S/D region all at once. In this case, the gate electrode made of phosphorus-doped polysilicon etc. corresponds to the impurity diffusion layer provided in the semiconductor substrate of the present invention.

1. A method for manufacturing a semiconductor device, comprising:
forming a metal film on an impurity diffusion layer provided in a semiconductor substrate;
forming a protective film on the metal film;
thereafter forming a compound film from the metal film and the impurity layer by heat treating the semiconductor substrate on which the protective film is formed so that the metal film reacts with an upper part of the impurity diffusion layer to form the compound film, the metal film having a predetermined thickness so that an unreacted part of the metal film remains on an entire surface of the compound film after forming the compound film with a desired thickness; and
thereafter removing the protective film and the unreacted part of the metal film by using an etchant having a metal film etching rate that is larger than a compound film etching rate.

2. The method for manufacturing a semiconductor device according to claim 1, wherein the metal film etching rate of the etchant is larger than a protective film etching rate of the etchant.

3. The method for manufacturing a semiconductor device according to claim 1, wherein the semiconductor substrate comprises a silicon-on-insulator (SOI) substrate, the metal film comprises a titanium film, and the protective film comprises a titanium nitride film.

4. The method for manufacturing a semiconductor device according to claim 3, wherein the etchant comrpises a wet etchant solution including hydrofluoric acid.
